(19) United States
(12) Patent Application Publication
(10) Pub. No.: US 2009/0231800 A1
(43) Pub. Date: Sep. 17, 2009

(54) Blade Enclosure With Replaceable Hard Drives

(76) Inventors: John Franz, Houston, TX (US); John Grady, Cypress, TX (US); Belgie McClelland, Tomball, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/243,115

(22) Filed: Oct. 1, 2008

Related U.S. Application Data
(60) Provisional application No. 61/036,283, filed on Mar. 13, 2008.

(51) Int. Cl. H05K 5/00

(52) U.S. Cl. 361/679.37

(57) ABSTRACT

One embodiment has plural servers stacked in an enclosure. The servers have a front surface and at least two hard disk drives that are each hot-swappable and replaceable through an opening in the front surface.

### CROSS REFERENCE TO RELATED APPLICATIONS

This application claims benefit of provisional patent application Ser. No. 61/036,283, filed Mar. 13, 2008, titled “Blade Enclosure With Replaceable Hard Drives.”

### BACKGROUND

Blade computing represents a fast growing segment in the computing industry because of the compaction, consolidation, modularity, management, and maintenance of such computers. The growth in the use of blade computers has, however, led to ever increasing challenges in efficiently powering, cooling, and maintaining the blade computers.

In blade computers, challenges include attempts at minimizing the relatively high operational capital and recurring costs associated with enterprise environments having a relatively large number of blades. These challenges also include designing blade enclosures that facilitate maintenance of and access to blade components. In some server systems, no way exists to increase or decrease storage capacity without removing the blade from the enclosure and taking the blade offline.

### BRIEF DESCRIPTION OF THE DRAWINGS

FIG. 1 is a perspective view of a computer system in accordance with an exemplary embodiment of the present invention.

FIG. 2A is a perspective view of a blade or server computer in accordance with an exemplary embodiment of the present invention.

FIG. 2B is a front view of the blade or server computer of FIG. 2A in accordance with an exemplary embodiment of the present invention.

FIG. 3 is a flow diagram for servicing a hard disk drive in a blade in accordance with an exemplary embodiment.

### DETAILED DESCRIPTION

Embodiments in accordance with the present invention are directed to apparatus, systems, and methods for using blades or servers with removable hard drives. One embodiment is a blade or server with one or more hot-pluggable hard drives that are accessible from a front of the blade. The hard drives are placed in a front of the blade and are near or adjacent a top surface of the blade to provide easy and convenient access for maintenance. Further, hard drive placement at this location allows improved airflow and a location for internal processor placement.

In one embodiment, multiple blades are stacked or arranged in an enclosure that has both a pleasing aesthetic appearance and an efficient functional design. Each blade includes one or more hard drives. For example, each blade includes two, four, or more hard drives that are placed side-by-side along an upper or top portion of the housing of the blade.

The hard drives are easily accessible from the front face of the blade and enclosure and are hot-pluggable or hot-swappable. By way of example, the hard disk drives can be disconnected and connected independent of each other and support hot-swapping (i.e., the ability to add and remove devices to and from a computer or electronic device while the computer or electronic device is running with the operating system automatically recognizing the changed or newly added component).

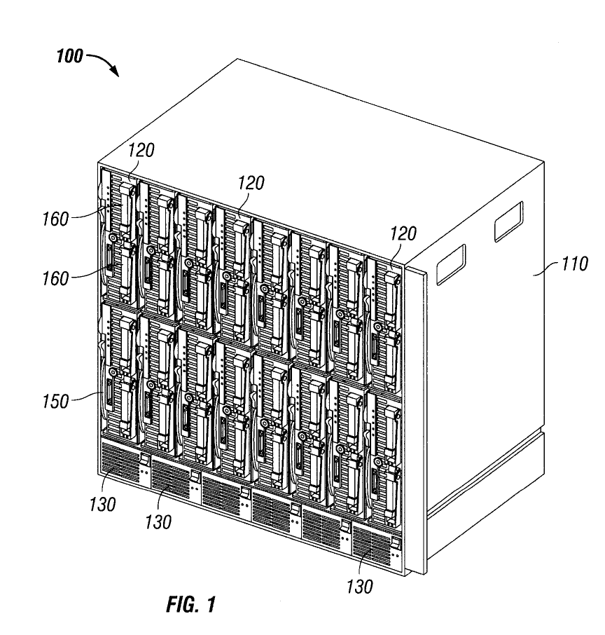

FIG. 1 shows a computer system 100 in accordance with an exemplary embodiment of the present invention. The system 100 includes a rack or an enclosure 110 housing a number of compute nodes 120, such as computer systems, servers, memories, hard drives, etc. For illustration, the compute nodes 120 are depicted as comprising blade servers or blade computers arranged in horizontal and vertical alignment with respect to each other in the enclosure 110. The compute nodes 120 are also depicted as including various components to form part of conventional electronic systems, such as various connectors, buttons, indicators, etc. In addition to the compute nodes 120, the enclosure 110 includes other components, such as one or more power supplies 130.

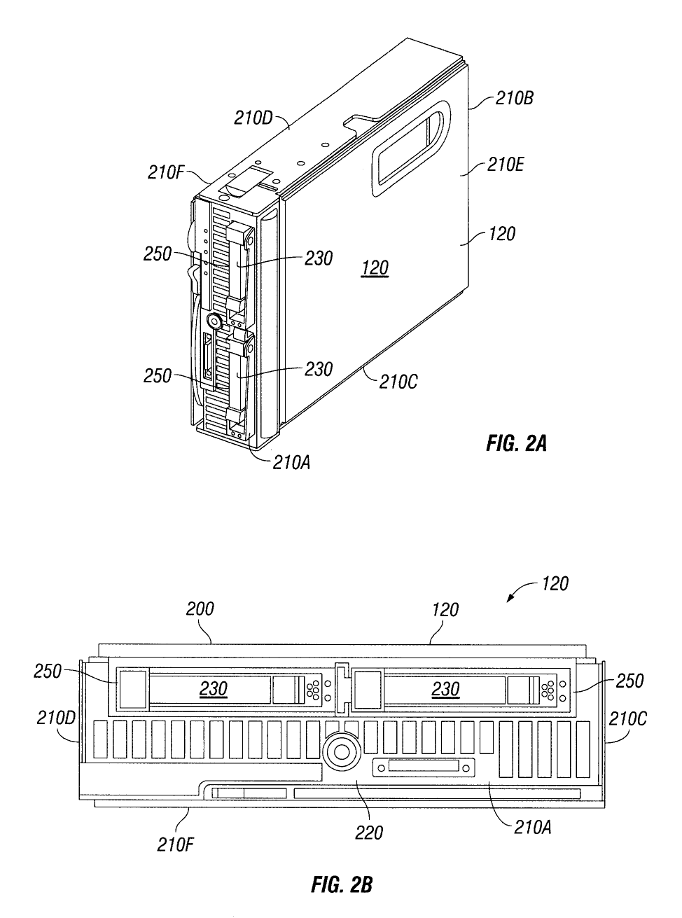

For illustration, each compute node 120 includes a handle 150 and one or more hard disk drives 160 (discussed in more detail in FIGS. 2A and 2B). The handle enables a user to remove the compute node from the enclosure.

Although sixteen compute nodes 120 and six power supplies 130 are illustrated as being contained in the enclosure 110, any reasonably suitable number of compute nodes 120 and power supplies 130 can be included in the enclosure without departing from a scope of the invention. In addition, the computer system 100 can include additional components, and some of the components depicted can be removed and/or modified without departing from exemplary embodiments.

It should also be understood that various embodiments of the invention are practiced in computer systems, storage systems, and other electronic environments having different configurations than the system 100 depicted in FIG. 1. By way of example, various embodiments of the invention are practiced in electronic environments having different types of compute nodes 120, for instance, in electronic environments having horizontally and/or vertically arranged servers.

Various embodiments of the invention are further practiced in systems and electronic environments containing a relatively larger number of compute nodes 120. For instance, various embodiments of the invention are practiced amongst compute nodes contained in a data center or compute nodes positioned at different geographic locations with respect to each other. The different geographic locations include, for instance, different rooms, different buildings, different counties, different countries, etc.

FIGS. 2A and 2B show a computer node 120 in accordance with an exemplary embodiment. For illustration, the compute node is shown as a blade computer or server.

The blade 120 has a rectangular shaped housing 200 having six surfaces or sides that include a front side 210A, a back or rear side 210B, two sides 210C and 210D, a top side 210E, and a bottom side 210F. The front side 210A includes one or more of indicator lights, switches, buttons, ports, connectors, etc. that are generally indicated at 220. The front side 210A also includes one or more hard disk drives 230.

Two hard disk drives 230 are positioned side-by-side along or adjacent to the top side or surface 210E of housing 200.The hard drives are not stacked on top of each other (such as being vertically stacked) but instead are placed next to each other along or parallel with the top surface 210E. Placing the hard drives in this location along a roof of the blade provides increased cooling and facilitates customer access.

In one embodiment, each hard disk drive 230 is hot-swappable and accessible from a front of the blade. For instance, if one of the hard drives fails or requires maintenance, a user can access and remove the hard drive through one or more openings 250 that are located in the front side 210A of the blade (as opposed to gaining access to the hard drive from the rear side 210B). The opening is provided in the housing 200 of the blade so a user can add or remove the hard disk drive from the blade.

In one embodiment, the hard drives have a form factor (i.e., size and shape) so two hard drives are placed side-by-side in a single blade computer. By way of example, each hard drive has dimensions of 6.0 inches (length) by 3.5 inches (width) by 0.6 inches (height). Each blade has dimensions of 20.0 inches (length) by 7.0 inches (width) by 2.0 inches (height).

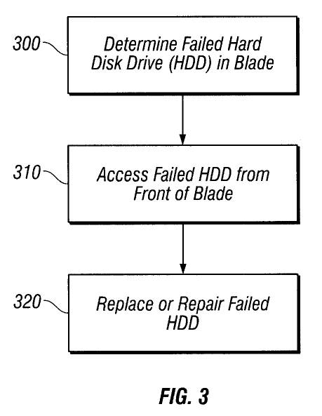

FIG. 3 is a flow diagram for servicing a hard disk drive in a blade in accordance with an exemplary embodiment. The exemplary method can be utilized, for example, for repairing, replacing, or otherwise accessing a hard disk drive in a blade or server of FIGS. 1-2. In one embodiment, the hard disk drives are modules that are removable and replaceable from the blade or server.

According to block 300, a determination is made that a hard disk drive in a blade requires service. By way of example, a hard disk drive can fail or otherwise need to be repaired or upgraded. A user could access the hard disk drives for other reasons as well.

According to block 310, the hard disk drive is accessed from a front of the blade and/or enclosure. As such, a user is not required to access the hard disk drive from the rear portion of the blade or from a rear of the enclosure. Instead, users can see and access the hard drives from the front of the computer without first moving the blade.

According to block 320, the hard disk drive is accessed and repaired or replaced. In one embodiment, the failed or damaged hard disk drive is hot-swapped with a new or different hard disk drive while the blade or server continues to operate. Thus, a user can service, remove, and/or replace a hard disk drive without being required to remove or move the blade while it is in the enclosure.

Exemplary embodiments enable a user to increase or decrease storage capacity (for example, hard disk drive) without removing the blade from the enclosure or taking the blade offline. For example, the failed hard disk drive can be replaced with another drive having more or less memory capacity (thus increasing or decreasing the storage capacity of the blade).

As used herein, a “blade” or “blade server” is a standardized electronic computing module that is plugged in or connected to a computer or storage system. A blade enclosure provides various services, such as power, cooling, networking, various interconnects and management service, etc for blades within an enclosure. Together the individual blades form a blade system. The enclosure (or chassis) performs many of the non-core computing services found in most computers. Further, many services are provided by the enclosure and shared with the individual blades to make the system more efficient. The specifics of which services are provided vary by vendor.

As used herein, the terms “hot swappable” or “hot-plug” or “hot-swapping” mean the ability to remove and replace an electronic component of a machine or system while the machine or system continues to operate. The individual hard drives can be hot swapped in the event they fail or need repair. Hot swapping enables one or more hard drives to be exchanged or serviced without impacting operation of the overall blade or enclosure in which the hard drive is located. For instance, in the event of a failure, the individual hard drive is removed from the blade and replaced with a new or different hard drive. The new hard drive is connected to the blade without disrupting continuous operation of the blade while it remains in the enclosure.

As used herein, the term “module” means a unit, package, or functional assembly of electronic components for use with other electronic assemblies or electronic components. A module is an independently-operable unit that is part of a total or larger electronic structure or device. Further, the module is independently connectable and independently removable from the total or larger electronic structure.

In one exemplary embodiment, one or more blocks or steps discussed herein are automated. In other words, apparatus, systems, and methods occur automatically. As used herein, the terms “automated” or “automatically” (and like variations thereof) mean controlled operation of an apparatus, system, and/or process using computers and/or mechanical/electrical devices without the necessity of human intervention, observation, effort and/or decision.

The methods in accordance with exemplary embodiments of the present invention are provided as examples and should not be construed to limit other embodiments within the scope of the invention. For instance, blocks in diagrams or numbers (such as (1), (2), etc.) should not be construed as steps that must proceed in a particular order. Additional blocks/steps can be added, some blocks/steps removed, or the order of the blocks/steps altered and still be within the scope of the invention. Further, methods or steps discussed within different figures can be added to or exchanged with methods of steps in other figures. Further yet, specific numerical data values (such as specific quantities, numbers, categories, etc.) or other specific information should be interpreted as illustrative for discussing exemplary embodiments. Such specific information is not provided to limit the invention.

In the various embodiments in accordance with the present invention, embodiments are implemented as a method, system, and/or apparatus. As one example, exemplary embodiments and steps associated therewith are implemented as one or more computer software programs to implement the methods described herein. The software is implemented as one or more modules (also referred to as code subroutines, or “objects” in object-oriented programming). The location of the software will differ for the various alternative embodiments. The software programming code, for example, is accessed by a processor or processors of the computer or server from long-term storage media of some type, such as a CD-ROM drive or hard drive. The software programming code is embodied or stored on any of a variety of known media for use with a data processing system or in any memory device such as semiconductor, magnetic and optical devices, including a disk, hard drive, CD-ROM, ROM, etc. The code is distributed on such media, or is distributed to users from the memory or storage of one computer system over a network of some type to other computer systems for use by users of such other systems. Alternatively, the programming code is embodied in the memory and accessed by the processor using the bus. The techniques and methods for embodying software programming code in memory, on physical media, and/or distributing software code via networks are well known and will not be further discussed herein.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1) A computer system, comprising:
a plurality of servers arranged in an enclosure, wherein each server has a front face and at least two hard disk drives that are hot-swappable and removable through an opening in front face.

2) The computer system of claim 1, wherein a hard disk drive of a server is upgraded while the server continues to operate in the enclosure.

3) The computer system of claim 1, wherein storage capacity of a server is increased while the server continues to operate in the enclosure.

4) The computer system of claim 1, wherein the hard disk drives are removable from the servers without removing the servers from the enclosure.

5) The computer system of claim 1 wherein the hard disk drives are removable from the servers without taking the servers offline.

6) The computer system of claim 1, wherein each of two hard disk drives are positioned adjacent a top surface of a server.

7) The computer system of claim 1, wherein each of the two hard disk drives are arranged side-by-side.

8) A blade computer system, comprising:
a plural blade computers stacked in a rack, each blade computer having a front face and plural hard drives that are hot-swappable and removable through the front face.

9) The blade computer system of claim 8, wherein the hard drives are removable through an opening in the front face of each blade computer.

10) The blade computer system of claim 8, wherein a hard drive is removable through the front face of a blade computer while the blade computer remains online.

11) The blade computer system of claim 8, wherein a hard drive is removable through the front face of a blade computer without removing the blade computer from the rack.

12) The blade computer system of claim 8, wherein each of the blade computers has two hard drives that are positioned side-by-side adjacent a top surface of each blade computer.

13) The blade computer system of claim 8, wherein storage capacity of the blade computers is increased or decreased by replacing hard drives without removing the blade computers from the rack.

14) The blade computer system of claim 8, wherein storage capacity of the blade computers is increased or decreased by upgrading hard drives without taking the blade computers offline.

15) The blade computer system of claim 8, wherein the hard drives have a form factor so two hard drives are positioned side-to-side in a single blade computer.

16) A computer system, comprising:
plural servers stacked in an enclosure, the servers having a front surface and at least two hard disk drives that are each hot-swappable and replaceable through an opening in the front surface.

17) The computer system of claim 16, wherein the hard disk drives are hot-swappable while the servers continue to operate in the enclosure.

18) The computer system of claim 16, wherein storage capacity of a server is increased while the server continues to operate in the enclosure.

19) The computer system of claim 16, wherein the hard disk drives are removable from the servers without removing the servers from the enclosure.

20) The computer system of claim 16, wherein the hard disk drives are removable from the servers without taking the servers offline.
